(19) United States
(12) Patent Application Publication
(10) Pub. No.: US 2010/0159120 A1
(43) Pub. Date: Jun. 24, 2010

(54) PLASMA ION PROCESS UNIFORMITY MONITOR

(75) Inventors: Joseph P. Dzengeleski, Newton, NH (US); George M. Gammel, Marblehead, MA (US); Bernard G. Lindsay, Danvers, MA (US); Vikram Singh, North Andover, MA (US)

Correspondence Address: VARIAN SEMICONDUCTOR EQUIPMENT ASSC., INC., 35 DORY RD., GLOUCESTER, MA, 01930-2297, US

(73) Assignee: Varian Semiconductor Equipment Associates, Inc., Gloucester, MA (US)

(21) Appl. No.: 12/341,574

(22) Filed: Dec. 22, 2008

(51) Int. Cl. C23C 14/48; B05C 11/00

(52) U.S. Cl. 427/8; 118/712

(57) ABSTRACT

An ion uniformity monitoring device is positioned within a plasma process chamber and includes a plurality of sensors located above and a distance away from a workpiece within the chamber. The sensors are configured to detect the number of secondary electrons emitted from a surface of the workpiece exposed to a plasma process. Each sensor outputs a current signal proportional to the detected secondary electrons. A current comparator circuit outputs a processed signal resulting from each of the plurality of current signals. The detection of the secondary electrons emitted from the workpiece during plasma processing is indicative of the uniformity characteristic across the surface of the workpiece and may be performed in situ and during on-line plasma processing.

### BACKGROUND OF THE INVENTION

1. Field of the Invention

Embodiments of the invention relate to the field of plasma processing systems. More particularly, the present invention relates to an apparatus and method for measuring the uniformity of a plasma process applied to a workpiece or wafer.

2. Discussion of Related Art

Ion implantation is a process used to dope ions into a work piece. One type of ion implantation is used to implant impurity ions during the manufacture of semiconductor substrates to obtain desired electrical device characteristics. An ion implanter generally includes an ion source chamber which generates ions of a particular species using, for example, a series of beam line components to control the ion beam and a platen to secure the wafer that receives the ion beam. These components are housed in a vacuum environment to prevent contamination and dispersion of the ion beam. The beam line components may include a series of electrodes to extract the ions from the source chamber, a mass analyzer configured with a particular magnetic field such that only the ions with a desired mass-to-charge ratio are able to travel through the analyzer, and a corrector magnet to provide a ribbon beam which is directed to a wafer orthogonally with respect to the ion beam to implant the ions into the wafer substrate. The ions lose energy when they collide with electrons and nuclei in the substrate and come to rest at a desired depth within the substrate based on the acceleration energy. The depth of implantation into the substrate is based on the ion implant energy and the mass of the ions generated in the source chamber. Typically, arsenic or phosphorus may be doped to form n-type regions in the substrate and boron, gallium or indium are doped to create p-type regions in the substrate.

Ion implanters as described above are usually associated with relatively high implant energies. When shallow junctions are required in the manufacture of semiconductor devices, lower ion implant energies are necessary to confine the dopant material near the surface of the wafer. In these situations, plasma deposition (PLAD) systems are used where the depth of implantation is related to the voltage applied between the wafer and an anode within a plasma processing chamber. In particular, a wafer is positioned on a platen which functions as a cathode within the chamber. An ionizable gas containing the desired dopant materials is introduced into the plasma chamber. The gas is ionized by any of several methods of plasma generation, including, but not limited to DC glow discharge, capacitively coupled RF, inductively coupled RF, etc. Once the plasma is established, there exists a plasma sheathe between the plasma and all surrounding surfaces, including the workpiece. The platen and workpiece are then biased with a negative voltage in order to cause the ions from the plasma to cross the plasma sheathe and be implanted into the wafer at a depth proportional to the applied bias voltage. Presently, a Faraday cup is used to measure the implant dosage amount to a wafer. However, a Faraday cup only provides information related to the total ion charge count but does not offer any insight into uniformity. Presently, measurement of plasma uniformity is inferred through the use of a Langmuir probe. This probe is positioned within the plasma chamber before an implant process begins or after it ends. The probe is biased to provide a current/voltage characteristic representing the current to the probe from the plasma ions and electrons as a function of the probe's bias and location. Although this measurement technique may be performed in situ, it cannot be performed during the implant, therefore it does not provide measurement information on-line during the implantation process. Plasma and process conditions may change in the time between the pre-implant measurement and the actual implant due to various factors including wafer surface conditions, plasma ionization, etc. Thus, there is a need to provide a uniformity monitoring device that is used in situ within a plasma chamber during the implantation process which provides accurate plasma implantation uniformity information in two dimensions across the surface of a target wafer or workpiece.

### SUMMARY OF THE INVENTION

Exemplary embodiments of the present invention are directed to an plasma process uniformity monitoring device. In an exemplary embodiment, a plasma process uniformity monitoring device is positioned within a plasma process chamber and includes a plurality of sensors located above a workpiece within the chamber. Each of the sensors is configured to detect the secondary electrons emitted from a surface of the workpiece exposed to a plasma process. Each sensor outputs a current signal proportional to the number of detected secondary electrons. A current comparator circuit is connected to each of the plurality of sensors and is configured to receive each of the current signals from the sensors. The current comparator circuit outputs a differential current signal resulting from each of the plurality of current signals. If the plasma process is uniform across the surface of the workpiece, then the current signals from the sensors will be equal and the differential current signal from the current comparator circuit will be near zero. However, if the differential current signal is not zero or near zero, then the current signals associated with the sensors are not equal, indicating that one or more of the sensors is receiving a greater or lesser number of secondary electrons from a corresponding surface area of the workpiece. The existence of a differential current signal indicates that the plasma processing of the workpiece is non-uniform.

### BRIEF DESCRIPTION OF THE DRAWINGS

FIG. 1 is a schematic illustration of a monitoring device within a plasma chamber in accordance with an embodiment of the present invention.

FIG. 2 is a schematic view of a monitoring device within a plasma chamber during an exemplary plasma implantation operation in accordance with an embodiment of the present invention.

FIG. 3 is a cross-sectional view of a gas baffle incorporating a plurality of sensors in accordance with an embodiment of the present invention.

FIG. 4 is a flow chart illustrating the steps of uniformity monitoring in accordance with and embodiment of the present invention.

### DESCRIPTION OF EMBODIMENTS

The present invention will now be described more fully hereinafter with reference to the accompanying drawings, in which preferred embodiments of the invention are shown. This invention, however, may be embodied in many different forms and should not be construed as limited to the embodiments set forth herein. Rather, these embodiments are provided so that this disclosure will be thorough and complete, and will fully convey the scope of the invention to those skilled in the art. In the drawings, like numbers refer to like elements throughout.

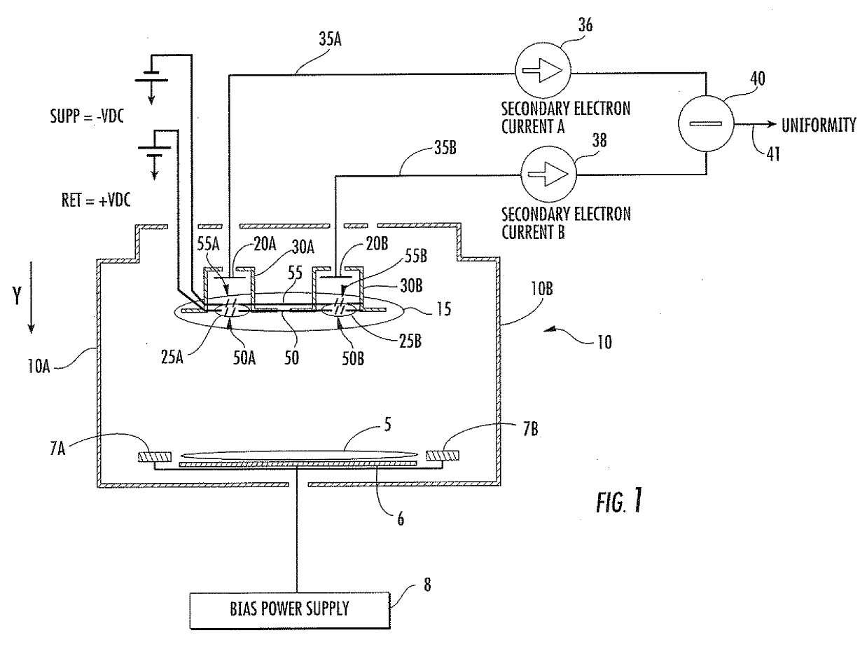

FIG. 1 is a schematic view of the monitoring device used in a plasma deposition (PLAD) system. A PLAD system may be, for example, a plasma etching tool, a plasma deposition tool or a plasma doping tool. The monitoring device in this PLAD system includes a plurality of sensors 20A, 20B mounted within a baffle 15 in plasma chamber 10. Baffle 15 may be, for example, a gas baffle positioned a distance above a workpiece 5 at one end of the plasma chamber which is configured to receive plasma processing for implantation into the workpiece 5. The workpiece may be, for example, a semiconductor wafer mounted on a platen 6 which supports the workpiece and provides an electrical connection thereto. A gas source (not shown) introduces ionizable gas into chamber 10 above the baffle 15 in direction Y at a desired pressure and flow rate. The baffle 15 disperses the gas within the chamber. Although a gas baffle 15 is disclosed, any device positioned above the workpiece 5 which is configured to disburse the gas introduced into the chamber may be employed. The gas is ionized by any of several known techniques. A bias power supply 8 provides a voltage pulse to the, platen 6, workpiece 5, and Faradays 7A and 7B which is negative with respect to an anode formed by the walls 10A and 10B and the gas baffle 15 of chamber 10. The voltage pulses accelerate the ions within the plasma which implant into workpiece 5 as an ion dose to form areas of impurity dopants within the workpiece. The voltage applied to platen 6 which is thereby applied to workpiece 5 attracts the ions across the plasma sheath for implantation. The amplitude of the voltage pulses correspond to the implantation depth of the ions into the workpiece. The dose rate and uniformity of implantation are influenced by the gas pressure, gas flow rate, gas distribution, position of the anode and the duration of the pulses, etc. The ion dose is the number of ions implanted into workpiece 5 which is equal to the integral over time of the ion current. The ion dose may be measured by a pair of Faraday cups 7A and 7B positioned contiguous with the workpiece 5 and pulsed simultaneously with the workpiece 5.

The baffle 15 includes a plurality of apertures 25A, 25B positioned radially along the surface of the baffle. Cups 30A and 30B are aligned with respective apertures 25A and 25B within which sensors 20A and 20B are housed. The cups shown in FIG. 1 are exaggerated for ease of explanation and would typically correspond with the cross sectional thickness of baffle 15. Although the present description of the sensors is disclosed as being integrally formed with baffle 15, the sensors may be housed separately and mounted to baffle 15 or positioned above workpiece 5 separately from baffle 15. Low voltage electrostatic grids 50 and 55, configured in front of the detectors 20A and 20B, are used to discriminate between relatively high energy, implant generated, secondary electrons and low energy plasma ions and electrons. In particular, a first grid 50 is disposed between sensors 20A, 20B and workpiece 5 and extends across apertures 25A and 25B. Grid 50 includes a plurality of screen portions 50A and 50B aligned with apertures 25A and 25B respectively to allow secondary electrons to pass through the apertures to sensors 20A and 20B. Because apertures 25A and 25B are not biased, they do not suffer from unwanted deposition or erosion from the secondary electrons or the low energy plasma ions and electrons passing through the apertures. Grid 50 is biased with a positive DC voltage (+VDC) and is configured to prevent low energy ions from the plasma within chamber 10 from leaking to sensors 20A and/or 20B during implantation. A second grid 55 is disposed between sensors 20A, 20B and first grid 50 and extends across apertures 25A and 25B. Grid 55 includes a corresponding plurality of screen portions 55A and 55B aligned with apertures 25A and 25B respectively to allow implant generated secondary electrons to pass through the apertures to sensors 20A and 20B. Grid 55 is biased with a negative DC voltage (−VDC). This negative voltage is substantially below the energy of the implant generated secondary electrons. Thus, when secondary electrons pass through apertures 25A and 25B within a corresponding cup 30A and/or 30B, they are counted by one of the respective sensors 20A or 20B. In addition, relatively low energy secondary electrons are generated at the surface of the sensor 20a or 20B by the implant generated secondary electrons' impact with the sensor 20A or 20B, the negative voltage on the inner grid 55 is set high enough to repulse these particles back toward the sensor so they may be collected and counted by the sensor, keeping the measurement true. Grid 55 serves another purpose in that it disallows relatively low energy plasma electrons from entering the cup 30A or 30B by repulsing them back toward the plasma 12.

As will be described in more detail below, sensor 20A detects the number of relatively high energy, implant generated, secondary electrons which pass through aperture 25A and generates a current signal 36 proportional to the number of secondary electrons detected. These secondary electrons are generated above the region of workpiece 5 aligned with aperture 25A. The current signal 36 is supplied to current comparator circuit 40 via connection 35A. Similarly, sensor 20B detects the number of secondary electrons which pass through aperture 25B and generates a current signal 38 proportional to the number of secondary electrons detected. These secondary electrons are generated above the region of workpiece 5 aligned with aperture 25B. The current signal 38 is supplied to current comparator circuit 40 via connection 35B. Current comparator circuit 40 compares the current signals 36 and 38 and outputs a differential current signal 41. If the current signals 35A and 35B are equal, the differential current signal 41 will be zero indicating that the plasma process is equal at the two regions on the workpiece aligned with apertures 25A and 25B If the current signals 35A and 35B are different, then the differential current signal 41 will not be zero indicating that the plasma process is not equal in these two regions of the workpiece 5. As can be inferred from the above description, the more sensors used to detect secondary electrons emitted from the surface of workpiece 5 the more information one obtains regarding process uniformity across the workpiece. In addition, if a particular plasma recipe requires a desired non-uniformity characteristic across workpiece 5 or a recurring non-uniform characteristic, then current comparator circuit provides the compared current calculation associated with each of the sensors 20A, 20B.

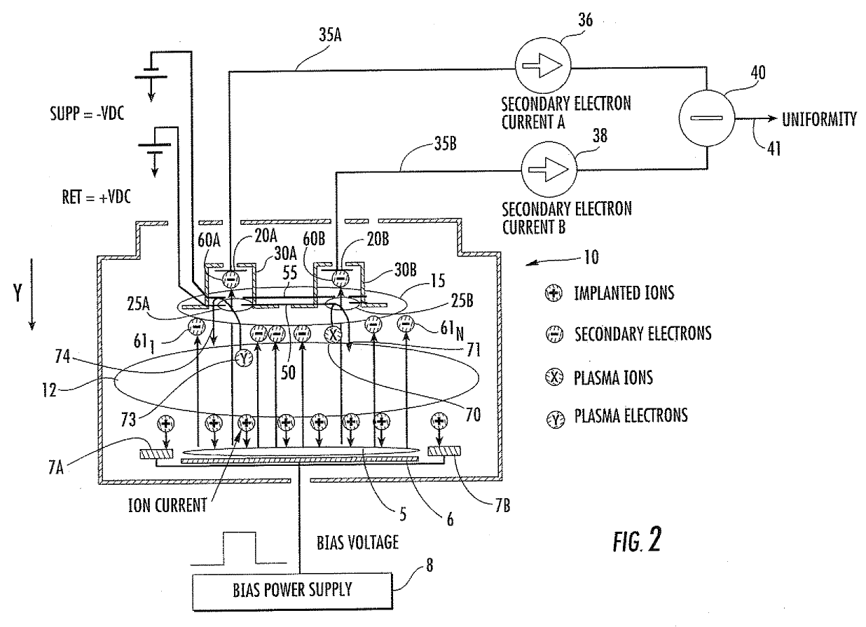

FIG. 2 is a schematic view of the monitoring device having a plurality of sensors 20A, 20B during a plasma implantation operation. In particular, an ionizable gas is introduced into chamber 10 above baffle 15 in direction Y at a desired pressure and flow rate. Plasma 12 is then created in the plasma chamber 10 by addition of energy by any of the known methods. Bias power supply 8 provides a negative voltage bias to workpiece 5 with respect to the anode formed by the walls of chamber 10 and the gas baffle 15. This causes positive ions (depicted with a “+” sign in FIG. 2) to be accelerated through plasma sheath 12 and implanted into workpiece 5 to form a uniform distribution of impurity dopants within workpiece 5. When the ions are implanted into workpiece 5, secondary electrons (depicted with a “−” sign in FIG. 2) are emitted from the surface of workpiece 5 which are then accelerated orthogonally toward baffle 15. The energy of the secondary electrons is determined by the implant bias voltage as the electrons are accelerated through the plasma sheath 12 above workpiece 5. This energy is substantially equal to the energy of the implanted ions. These secondary electrons are detected by the sensors and a proportional current signal is generated and compared with the currents generated by the other sensors positioned above the surface of the workpiece. For example, secondary electrons 60A and 60B are emitted from the surface of workpiece 5 orthogonally aligned with cavities 30A and 30B via apertures 25A and 25B respectively. Secondary electrons 60A and 60B pass through screen portions 50A and 50B of first grid 50 and screen portions 55A and 55B of second grid 55 and are received by sensors 20A and 20B. In response to the detection of secondary electrons 60A, sensor 20A generates current 36 and supplies it to comparator circuit 40 via line 36. Similarly, in response to the detection of secondary electrons 60B, sensor 20B generates current 38 and supplies it to comparator circuit 40 via line 35B. Current comparator circuit 40 compares the current signals 36 and 38 and outputs a differential current signal 41. Because a differential current signal is being evaluated based on the detected secondary electrons, it is not critical to determine the absolute number of secondary electrons produced by ions impacting the surface of the workpiece. Rather, the differential current signal indicates that the number of electrons detected at the respective locations of the sensors 20A, 20B is equivalent or not equivalent. As noted briefly above, a particular recipe may require a non-uniform implantation or non-uniform characteristic associated with particular locations across the wafer. In this case, current comparator circuit would provide a particular current signal in response to this non-uniformity.

Secondary electrons 61₁-61_{N} which are emitted orthogonally from the surface of workpiece 5 as indicated by arrows 62₁-62_{N} are not aligned with either cavity 30A or 30B and thus, are not detected by sensors 20A and 20B. Again, the depiction of sensors 20A and 20B in FIG. 2 is for ease of explanation and the monitoring device utilized in chamber 10 has a sufficient number of sensors to accurately provide a uniformity measurement. Low energy plasma ions 70 (depicted with an “x” in FIG. 2) which is aligned with aperture 25A or 25B is prevented from entering the sensor 20A or 20B by grid 50 which is biased with a positive voltage that exceeds the energy of the plasma ion. Low energy plasma ion 70 is repelled back toward the plasma 12 as indicated by arrow 71. Plasma electron 73 may also pass through aperture 25A or 25B. This representative plasma electron passes through aperture 25A and gains energy form the positive bias on grid 50, but because grid 55 is biased with a negative DC voltage (−VDS) which exceeds the bias on grid 50, plasma electron 73 is repelled back toward grid 50 and the plasma 12 as indicated by arrow 74. In this manner, the monitoring device detects the secondary electrons emitted from the surface of workpiece 5 in situ and during ion implantation to monitor the uniformity of the plasma process taking place.

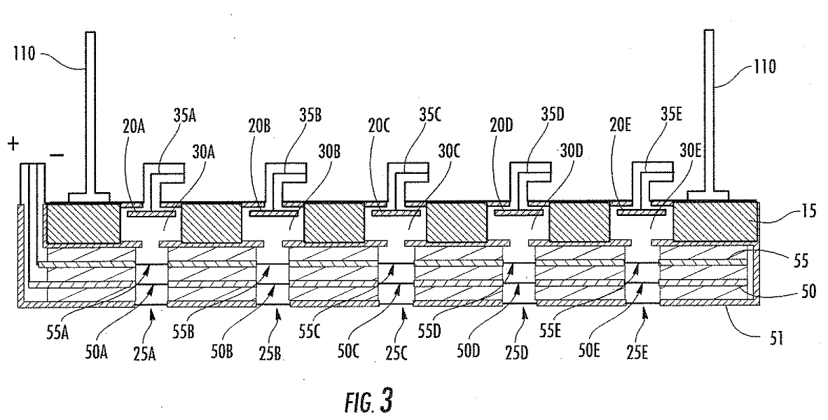

FIG. 3 is a schematic cross-section of an alternative embodiment of baffle 15 incorporating multiple sensors 20A-20E radially across the baffle. As noted above, baffle 15 is positioned above a workpiece within a plasma chamber by support members 110. Alternatively, this type of structure could be an integral part of the plasma chamber. Baffle 15 includes a plurality of cavities 30A-30E where each cavity houses a respective sensor 20A-20E. Although the cavities 30A-30E are illustrated as equally spaced radially across baffle 15, the positioning and location of the cavities is at the discretion of the user. Each of the sensors 20A-20E is connected to a comparator circuit (similar to comparator circuit 40 illustrated in FIGS. 2 and 3) via respective lines 35A-35E. A ground plane 51 is disposed between grid 50 and workpiece 5. Ground plane 51 acts as a shield for plasma contained within chamber 10. In particular, the interior of chamber 10 is at an equipotential such that the plasma within the chamber is surrounded by ground potential. A plurality of apertures 25A-25E located across ground plane 51 are aligned with each of the sensors 20A-20E. Grid 50 extends across each of the cavities 30A-30E and includes corresponding screen portions 50A-50E aligned with apertures 25A-25E and sensors 20A-20E respectively. Again, grid 50 is biased with a positive DC voltage (+VDC) to prevent low energy plasma ions from reaching sensors 20A-20E. Similarly, grid 55 extends across each of the cavities 30A-30D and includes corresponding screen portions 55A-55E aligned with apertures 25A-25E and sensors 20A-20E respectively. Grid 55 is biased with a negative DC voltage (−VDC) used to trap the secondary electrons in cavities 30A-30E and detected by sensors 20A-20E as well as repelling plasma electrons back toward the plasma. In this manner, a plurality of sensors 20A-20E are integrally formed within baffle 15 to detect secondary electrons emitted from a workpiece and accelerated orthogonally within a plasma chamber. By using sufficiently sized apertures the secondary electrons are detected or sampled from a relatively large area of workpiece 5 and therefore, is not subject to local differences in secondary emissions or photoresist coverage present on the workpiece.

In addition to monitoring uniformity during implant, by controlling the biasing voltages to grids 50 and 55, the plasma within the chamber 10 may be characterized before an implant begins. For example, the positive bias can be held at a constant voltage on grid 50 while the negative bias on grid 55 is swept over a range of voltages The output from each of the sensors, monitored during the voltage sweep, will describe the energy distribution of electrons in the plasma. Similarly, the positive voltage can be swept, describing the energy distribution of the plasma ions. Those skilled in the art can extract more information about the plasma by manipulation of these voltages. In an alternative configuration, the sensors 20A-20E themselves can be biased either positively or negatively, with or without the grids being biased, to extract plasma characteristics.

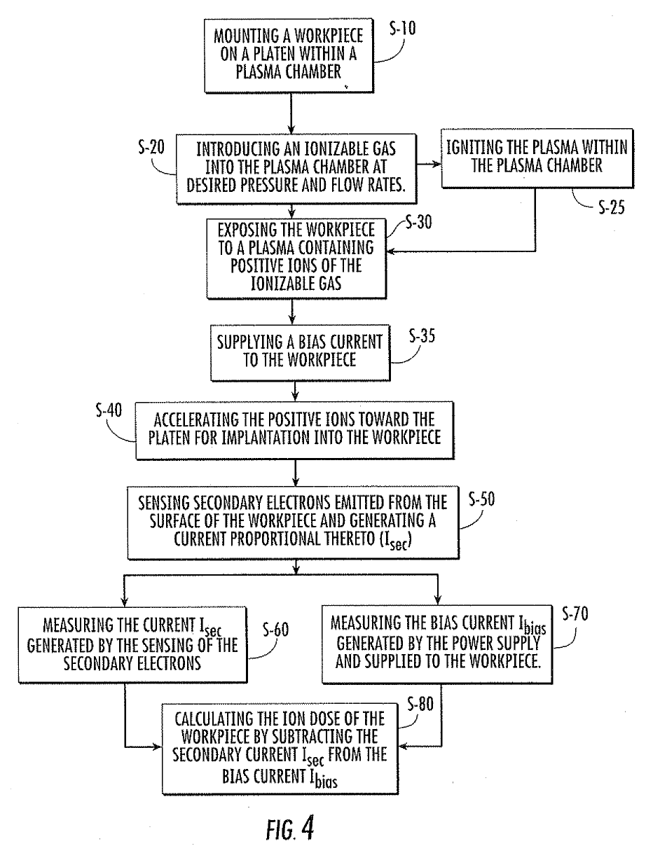

FIG. 4 is a flow diagram illustrating the steps associated with monitoring the uniformity of a plasma implantation process. A workpiece 5 is mounted on a platen or support within a plasma chamber 10 at step S-10. An ionizable gas is introduced into the plasma chamber at step S-20 and the plasma is ignited at step S-25. The workpiece 5 is exposed to a plasma containing positive ions contained in the ionizable gas at step S-30. The workpiece 5 is biased with a current I_{bias} supplied by power supply 8 at step S-35. The positive ions are accelerated to an implant energy toward the platen for implantation into the workpiece 5 at step S-40. At steps S-50 and S-60, secondary electrons which are emitted from a plurality of locations across the surface of workpiece 5 when the plasma ions are implanted into the workpiece are sensed by a plurality of sensors 20A-20E. A current signal generated by sensing of the secondary electrons from each of the plurality of sensors 20A-20E is measured at step S-70.

While the present invention has been disclosed with reference to certain embodiments, numerous modifications, alterations and changes to the described embodiments are possible without departing from the sphere and scope of the present invention, as defined in the appended claims. Accordingly, it is intended that the present invention not be limited to the described embodiments, but that it has the full scope defined by the language of the following claims, and equivalents thereof.

What is claimed is:

1. A process uniformity monitoring device within a plasma process chamber, said monitoring device comprising:
a plurality of sensors positioned orthogonal to a workpiece within said chamber, each of said sensors configured to detect the number of electrons emitted from a surface of said workpiece exposed to a plasma processing and output a current signal proportional to said number of detected electrons; and
a current signal processing circuit connected to each of said plurality of sensors and configured to receive each of said current signals from each of said sensors, said current processing circuit configured to output a signal from each of said plurality of current signals wherein said plurality of current signals is representative of the uniformity of the plasma process.

2. The process uniformity monitoring device of claim 1 further comprising a monitoring device housing having a plurality of cavities corresponding to said plurality of sensors, each of said cavities defining an aperture through which said electrons pass and configured to mount a respective sensor therein.

3. The process monitoring device of claim 2 wherein said device housing is mounted on a gas baffle within said process chamber.

4. The process uniformity monitoring device of claim 1 wherein said plurality of sensors are integrally formed in a gas baffle within said process chamber.

5. The process uniformity monitoring device of claim 1 further comprising a grid disposed between said plurality of sensors and said workpiece, said grid biased with a positive DC voltage and configured to prevent low energy ions from said plasma from leaking to any one of said plurality of sensors.

6. The process uniformity monitoring device of claim 5 wherein said grid is a first grid, said monitoring device further comprising a second grid disposed between said first grid and said plurality of sensors, said second grid biased with a negative DC voltage to prevent low energy plasma electrons and negative ions from entering any one of said plurality of sensors and configured to trap secondary electrons that are generated within a respective one of said sensors.

7. The process uniformity monitoring device of claim 1 wherein said plurality of current signals indicates a profile of the process taking place.

8. The process uniformity monitoring device of claim 1 wherein said sensors are positioned radially from a central axis with respect to said workpiece.

9. A plasma processing system comprising:
a plasma processing chamber configured to receive an ionizable gas;
a platen mounted in said plasma processing chamber for supporting a workpiece;
a source of ionizable gas coupled to said chamber, said ionizable gas containing a desired dopant or chemistry for processing said workpiece;
a plasma source for producing a plasma containing positive or negative ions of said ionizable gas, and accelerating said ions toward said platen for processing said workpiece; and
a plurality of sensors disposed above said workpiece within said plasma processing chamber, each of said sensors configured to detect the number of secondary electrons emitted from said workpiece while said plasma is processing said surface of said workpiece, each of said sensors configured to output a current signal proportional to said number of detected secondary electrons.

10. The plasma processing system of claim 9 further comprising a current signal processing circuit connected to each of said plurality of sensors, said signal processing circuit configured to receive each of said current signals from each of said sensors and output a differential signal from each of said plurality of processed current signals.

11. The plasma processing system of claim 9 further comprising a monitoring device housing having a plurality of cavities corresponding to said plurality of sensors, each of said cavities defining an aperture through which said secondary electrons pass and configured to mount a respective sensor therein.

12. The plasma processing system of claim 11 wherein said device housing is mounted on a gas baffle within said plasma processing chamber.

13. The plasma processing system of claim 11 wherein said plurality of sensors are integrally formed in a gas baffle within said plasma processing chamber.

14. The plasma processing system of claim 11 further comprising a grid disposed between said plurality of sensors and said workpiece, said grid biased with a positive DC voltage and configured to prevent low energy ions passing through any one said apertures toward said corresponding one of a plurality of sensors.

15. The plasma processing system of claim 14 wherein said grid is a first grid, said plasma processing system further comprising a second grid disposed between said first grid and said plurality of sensors, said second grid biased with a negative DC voltage and configured to disallow low energy plasma electrons from entering said cavities and trap said process induced secondary electrons within a respective one of said cavities.

16. The plasma processing system of claim 10 wherein said processed current signal indicates a profile of a relative number of secondary electrons across each of said sensors.

17. The plasma processing system of claim 9 wherein said plurality of sensors are positioned radially from a central axis with respect to said workpiece.

18. A method of monitoring plasma process uniformity comprising:
mounting a workpiece on a platen within a plasma chamber;
introducing an ionizable gas into said plasma chamber;
exposing said workpiece to a plasma containing positive ions of said ionizable gas;
accelerating said positive ions to an implant energy by biasing of the workpiece;
directing said accelerated ions toward said platen for processing of said workpiece; and
sensing secondary electrons emitted from a plurality of locations across a surface of said workpiece when said plasma ions are processing said workpiece.

19. The method of monitoring plasma process uniformity of claim 18 further comprising measuring a current signal generated by said sensing of said secondary electrons from each of said plurality of locations.

20. The method of monitoring plasma process uniformity of claim 19 further comprising comparing each of said current signals and outputting a processed signal resulting from the comparison of each of said current signals wherein said processed signal is indicative of the uniformity of said plasma process of said workpiece.
